(19) United States
(12) Patent Application Publication
(10) Pub. No.: US 2016/0329516 A1
(43) Pub. Date: Nov. 10, 2016

(54) OLED DEVICE

(71) Applicant: EverDisplay Optronics (Shanghai) Limited, Shanghai (CN)

(72) Inventors: Mou Xin, Shanghai (CN); Yanhu Li, Shanghai (CN); Zhao Wang, Shanghai (CN); Mingyue Zhang, Shanghai (CN)

(21) Appl. No.: 15/147,186

(22) Filed: May 5, 2016

(30) Foreign Application Priority Data
May 6, 2015 (CN) 201510228274.0

(51) Int. Cl. H01L 51/50

(52) U.S. Cl. CPC H01L 51/5096; H01L 51/5072; H01L 51/5012; H01L 51/5056; H01L 51/5088; H01L 2251/558

(57) ABSTRACT

The invention relates to the field of semiconductor technology, and more particularly, to an OLED device, configuring a RCLEL layer between an electron transport layer and a hole transport layer, the RCLEL layer restricts accumulation of charges in the interface of the electron transport layer and the hole transport layer, and prevents the accumulated charges forming non-light-emitting center in the interface, and the RCLEL layer has reversible electrochemical redox properties, so as to slow down the metamorphism of the material in the transmission process of electrons and holes and prevent the diffused ions and impurities entering the light emitting layer, thereby improving the life of the device.

### CROSS-REFERENCE TO RELATED APPLICATIONS

The present application claims priority to and the benefit of Chinese Patent Application No. CN 201510228274.0 filed on May 6, 2015, the entire content of which is incorporated herein by reference.

### BACKGROUND OF THE INVENTION

1. Field of the Invention

The invention relates to the field of semiconductor technology, more specifically, to an OLED device.

2. Description of the Related Art

OLED (organic light-emitting diode) has features of self-luminous, simple structure, ultra-thin, fast response, wide viewing angle, low power consumption and the properties capable of flexible display, and is known as the “dream display” and the most ideal next generation of flat panel display technology. However, OLED is currently only used in mobile phones and tablets, the life thereof has been one of the important restriction factors of the applications of OLED in the field of television and vehicles, therefore, the improving of the life of OLED will help the applications thereof to be expended.

There are many technologies and structures of improving the efficiency of OLED and reducing the driving voltage thereof, but one of the reasons that constraints the widespread use of OLED is its life is nothing compared to LCD, LED, etc. The factors affect the life of OLED have quite a lot: the mechanism thereof is very complex, and there is no theory can perfectly explain the life decay of OLED, and its attenuation mechanism can be divided as intrinsic deterioration and extrinsic deterioration.

Extrinsic degradation is a decline caused by the factors aside from the factors of the material and structure of the OLED device, such as the flatness of the substrate, the pollution of tiny particles, tiny pinholes of the surface of electrode and water and oxygen permeability of encapsulation adhesive material.

The factors of intrinsic deterioration are very complex, which approximately can be divided into the following categories: 1) the stability of organic thin film and the low glass transition temperature may cause deterioration of the stability of the organic thin film, and easily leads to poor stability of the device, therefore, the glass transition temperature of the material is improved, the stability of the film is also improved and crystalline film is not easy to be formed; 2) the contact surface of the anode and the organic layer belong to different types of substances, which would cause the problem of poor adhesion of the contact surface, and the greater the energy level difference between the anode and the hole injection layer or the anode and the hole transport layer is, the more obvious the attenuation of the device will be, and the shorter the life will be; 3) the stability of the excited state: the more stable the excited state is, the longer the life of the device will be; 4) the electrochemical reversibility of the organic material: since the conductive process of current carriers in the organic thin film is a series of redox reactions, the reversible electrochemical redox properties of the organic material may improve the stability of the material, and avoid deterioration of the organic material which causes attenuation of brightness of the device; 5) the mobile ionic impurities: mobile ionic (such as 1N3+, Sn4+) caused by the diffusion of the electrodes is likely to become recombination center or quenched center of electrons and holes, thus causes recession of efficiency of the device and decline of life; and there is no function layer structure for the life of OLED has been disclosed yet.

### SUMMARY OF THE INVENTION

In view of the above problems, the invention provides an OLED device.

An OLED device comprises an electron transport layer, a light emitting layer, a hole transport layer and a hole injection layer, stacked successively;

wherein a RCLEL layer (Restricted Charge Accumulation Induced Lifetime Enhancement Layer) is disposed between the electron transport layer and the hole injection layer to balance carrier mobility in a film interface.

In the above OLED device, wherein, a first RCLEL layer is disposed between the electron transport layer and the light emitting layer, and/or

in the above OLED device, the OLED device further comprises a second RCLEL layer is disposed between the light emitting layer and the hole transport layer, and/or

in the above OLED device, wherein, electron mobility of the first RCLEL layer is greater than electron mobility of the electron transport layer, so as to prevent an accumulation of charges at the contact interface of the light emitting layer and the electron transport layer.

In the above OLED device, wherein, hole mobility of the second RCLEL layer is greater than hole mobility of the hole transport layer to prevent an accumulation of charge at a contact interface of the light emitting layer and the hole transport layer.

In the above OLED device, wherein materials of the first RCLEL layer, the second RCLEL layer and the RCLEL layer have reversible electrochemical redox properties.

In the above OLED device, wherein the materials of the first RCLEL layer, the material of the second RCLEL layer and the material of the RCLEL layer are different.

In the above OLED device, wherein, thicknesses of the first RCLEL layer, thickness of the second RCLEL layer and thickness of the RCLEL layer are 5-500 Angstroms.

In the above OLED device, wherein, the triplet state energy levels of the first RCLEL layer and the second RCLEL layer are both higher than triplet state energy level of the light emitting layer.

In the above OLED device, wherein, the material of the first RCLEL layer is an electron transport material or a hole blocking material, the material of the second RCLEL layer is a hole transport material or an electron blocking material, and the material of the RCLEL layer is a hole injection material or a hole transport material.

The above OLED device, wherein materials of the RCLEL layer and the electron transport layer are the same.

The above OLED device, wherein, the OLED device further comprises: a substrate, an anode, a buffer layer and a cathode on the electron transport layer, stacked successively under the hole injection layer.

In summary, the invention discloses an OLED device, providing a RCLEL layer between the electron transport layer and the light emitting layer, and/or the light emitting layer and the hole transport layer, and/or the hole injection layer and the hole transport layer; the RCLEL layer restricts the accumulation of charges in the interface of the electron transport layer and the light emitting layer and the interface of the hole transport layer and the light emitting layer, and prevents the accumulated charges forming a non-light-emitting center, reduces the device's decline, thereby increasing the life of the device; and the RCLEL layer prevents the diffused ions and impurities entering the light emitting layer, thereby reducing the luminescent quenching caused by the diffused ions and impurities, the material of the RCLEL has reversible electrochemical redox properties, so that the metamorphism of material in the transmission process of electrons and holes is slowed down, and the decline of the device is slowed down, too.

BRIEF DESCRIPTIONS OF THE DRAWINGS

The accompanying drawings, together with the specification, illustrate exemplary embodiments of the present disclosure, and, together with the description, serve to explain the principles of the present invention.

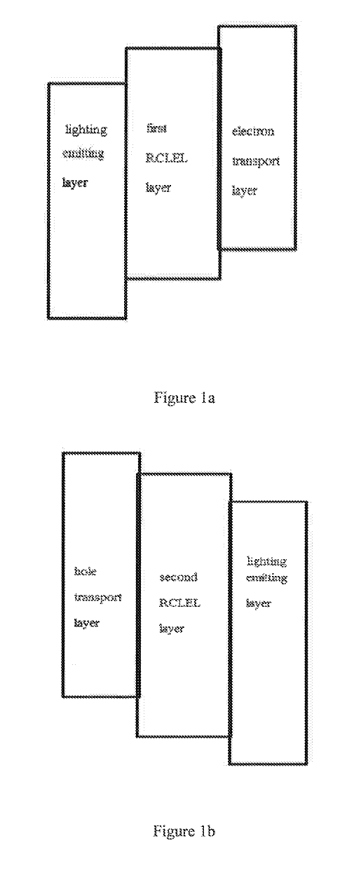

FIGS. 1a-1c are structure diagrams of the invention;

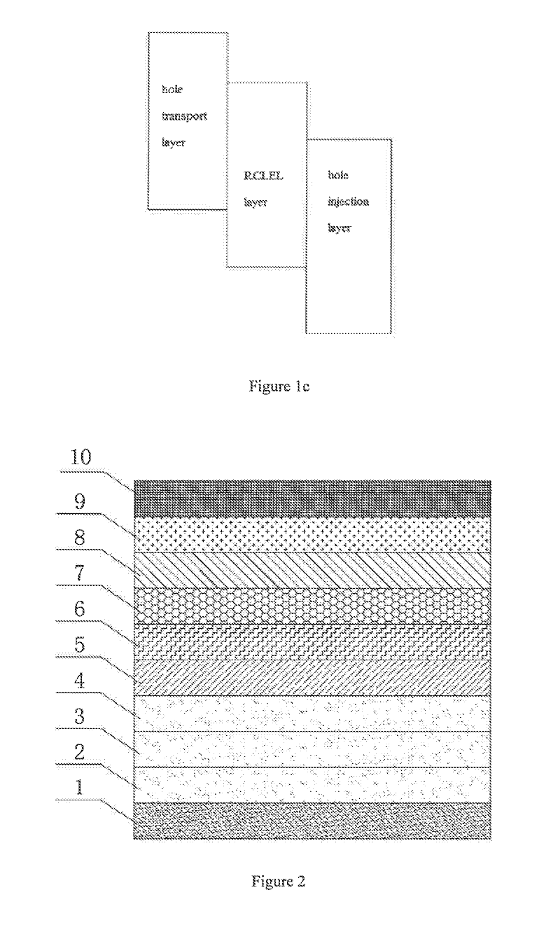

FIG. 2 is a structure diagram of an embodiment of the invention;

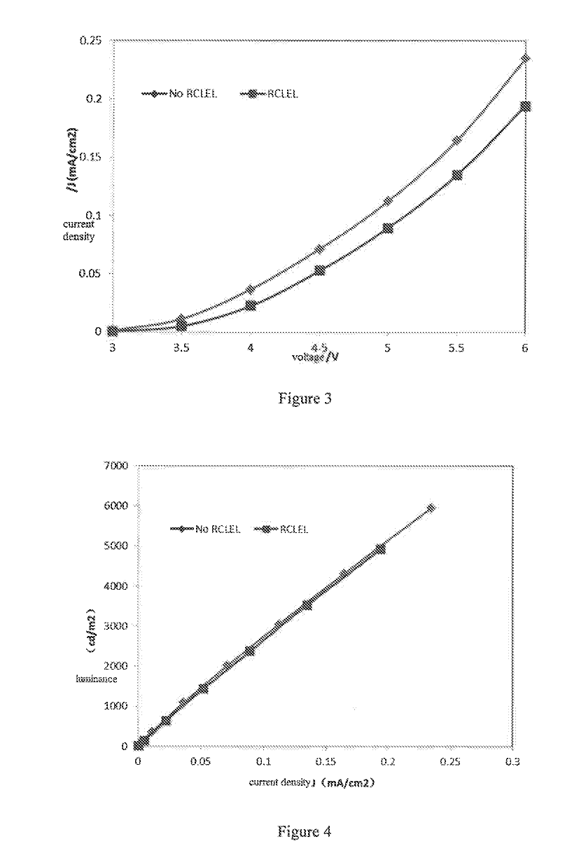

FIG. 3 is characteristic curves of the voltage and current density of RCLEL device of the embodiment of the invention;

FIG. 4 is a curve graph of the current density and brightness of RCLEL device of the embodiment of the invention;

FIG. 5 is a curve graph of the brightness and current efficiency of RCLEL device of the embodiment of the invention; and

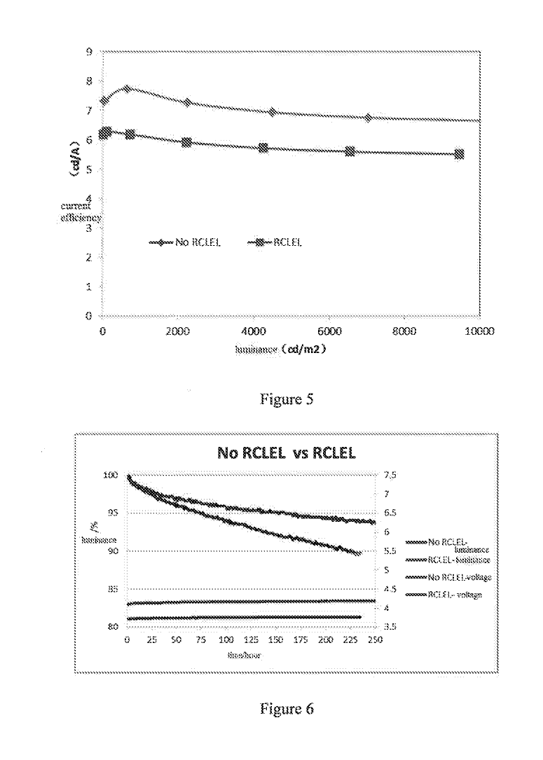

FIG. 6 is a curve graph of brightness percentage and time variation with/without the RCLEL device of the embodiment of the invention.

### DETAILED DESCRIPTION

The present invention will now be described more fully hereinafter with reference to the accompanying drawings, in which exemplary embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. Like reference numerals refer to like elements throughout.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” or “includes” and/or “including” or “has” and/or “having” when used herein, specify the presence of stated features, regions, integers, steps, operations, elements, and/or components, but do not preclude the presence or addition of one or more other features, regions, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

As used herein, “around”, “about” or “approximately” shall generally mean within 20 percent, preferably within 10 percent, and more preferably within 5 percent of a given value or range. Numerical quantities given herein are approximate, meaning that the term “around”, “about” or “approximately” can be inferred if not expressly stated.

As used herein, the term “plurality” means a number greater than one.

Hereinafter, certain exemplary embodiments according to the present disclosure will be described with reference to the accompanying drawings.

The core idea of the invention is providing a RCLEL layer (Restricted Charge Accumulation Induced Lifetime Enhancement Layer) between an electron transport layer and a light emitting layer, and/or a light emitting layer and a hole transport layer, and/or a hole injection layer and a hole transport layer; a faster electron mobility of the RCLEL layer can prevent accumulation of electrons in each layer of the interface, thereby ensuring balance of electrons and holes, reducing formation of non-light-emitting recombination centers, thereby enhancing life of the device.

As shown in FIGS. 1a-1c, the invention provides an OLED device. The OLED device comprises the electron transport layer, the light emitting layer, the hole transport layer and the hole injection layer;

a RCLEL layer is disposed between the electron transport layer and the hole injection layer to balance carrier mobility in a film interface,

a first RCLEL layer is disposed between the electron transport layer and the light emitting layer, and/or

a second RCLEL layer is disposed between the light emitting layer and the hole transport layer.

In the invention, configuring a RCLEL layer between the electron transport layer and the light emitting layer, and/or the light emitting layer and the hole transport layer is due to part of the electrons of the OLED device accumulate in the interface of the light emitting layer and the electron transport layer, and/or the light emitting layer and hole transport layer, thereby forming a non-light-emitting recombination center. After configuring the RCLEL layer, the first RCLEL layer and the second RCLEL layer, electron mobility of the first RCLEL layer is greater than electron mobility of the electron transport layer, and electron mobility of the second RCLEL layer is greater than electron mobility of the hole transport layer. Thus, the RCLEL layer, the first RCLEL layer and the second RCLEL layer can effectively district the accumulation of charges in the interface of the electron transport layer and the light emitting layer and the interface of the hole transport layer and the light emitting layer, to prevent the accumulated charges forming non-lighting-emitting center.

Wherein, the RCLEL, the first RCLEL layer and the second RCLEL layer can also prevent diffusible ions and impurities entering the light emitting layer, thereby reducing the emitting quenching caused by diffusible ions and impurities.

In the invention, the RCLEL layer is disposed between the hole injection layer and the hole transport layer. Hole mobility of the RCLEL layer is greater than the hole mobility of the hole injection layer, just like the first RCLEL layer and the second RCLEL layer, the RCLEL layer restricts the accumulation of charges in the interface of the hole injection layer and the hole transport layer.

The transport process of electrons and holes will cause deterioration of the RCLEL layer, the first RCLEL layer and the second RCLEL layer; in order to slow the material deterioration of the RCLEL layer, the first RCLEL layer and the second RCLEL layer, the RCLEL layer, the first RCLEL layer and the second RCLEL layer preferably are made of the material with reversible electrochemical redox properties, so that during transport process of electrons and holes, the material deterioration is slowed, and the life of RCLEL layer, the first RCLEL layer and the second RCLEL layer are extended.

In the invention, according to the actual preparation situation of the OLED device, the thicknesses of the RCLEL layer, the first RCLEL layer and the second RCLEL layer located between the electron transport layer and the light emitting layer, and/or the light emitting layer and the hole transport layer, and/or the hole injection layer and the hole transport layer are 5-500 Angstroms. The first RCLEL layer, the second RCLEL layer and the RCLEL layer are made from organic material, and the triplet state energy level of the organic material of the RCLEL layer, the first RCLEL layer and the second RCLEL layer are higher than the triplet state energy level of the light emitting material, so as to avoid the energy back to the organic material of the RCLEL layer, the first RCLEL layer and the second RCLEL layer from the light emitting material.

Because the first RCLEL layer, the second RCLEL layer and the RCLEL layer are disposed between different functional layers, according to the functional of the different functional layers, the materials of the first RCLEL layer, the second RCLEL layer and the RCLEL layer are not the same. In the invention, the material of the first RCLEL layer is an electron transport material or a hole blocking material, the material of the second RCLEL layer is a hole transport material or an electron blocking material, and the material of the RCLEL layer is a hole injection material or a hole transport material.

In the invention, preferred but not limited, the material of the first RCLEL layer is TPBI, the material of the second RCLEL layer is TCTA, the material of the RCLEL layer is HATCN.

In the invention, the material of the first RCLEL layer may be the same as or different from the material of the electron transport layer, the material of the second RCLEL layer may be the same as or different from the material of the hole transport layer.

To facilitate understanding of the structure of the invention, the following will be described with reference to specific embodiments.

The structure of the OLED device of the invention is:

As show in FIG. 2, to add a RCLEL layer between the electron transport layer and the light emitting layer, the basic structure is: substrate 1/anode 2/buffer layer 3/first hole injection layer 4/second hole injection layer 5/hole transport layer 6/emitting layer 7/RCLEL layer 8/electron transport layer 9/cathode 10, as shown in FIG. 3, in the graph the lateral direction indicates the voltage, the lengthways direction indicates the current density; with the same voltage, the current density of the device added the RCLEL layer is less than the device without the RCLEL layer, but the coincidence efficiencies of the two devices are almost the same (as shown in FIG. 4, the lateral direction represents current density, the lengthways direction represents luminance), which represents the current flow not recombined and leakage to the electrode of the device without the RCLEL layer is greater than the current flow not recombined and leakage to the electrode of the device added the RCLEL layer, that is to say, although the current density of the device without the RCLEL layer is larger at the same voltage, its balance factor of injected carrier is small, this will cause part of the charges accumulating in the interface of the light emitting layer and the hole/electron transport layer, thereby causing the device recession faster.

As shown in FIG. 5, in the graph, the lateral direction indicates the luminance, the lengthways direction indicates the current efficiency; as for the device without RCLEL layer, the current efficiency increases with the luminance, the current efficiency reaches to the maximum when the luminance is 630 cd/m²; the current efficiency gradually reduces when the luminance is higher than 630 cd/m², which also illustrates that the carriers of the device without the RCLEL layer are out of balance in different current densities, thereby causing the reduction of the efficiency and damaging the life of the device. However, the curve of the current efficiency and the luminance of the device added the RCLEL is more smooth, which facilitates to extend the life of OLED device.

As shown in FIG. 6, in the graph, the lateral direction indicates time, the lengthways direction indicates the luminance percentage; the attenuation ratio of the luminance percentage-time changing curve of the device added the RCLEL layer increases slower than the device without the RCLEL layer; the time that the luminance attenuates to a luminance, which has only 95% of the original luminance, (LT95) of the device added the RCLEL layer is 159 hours; the time that the luminance attenuates to LT95 of the device without the RCLEL layer is 74 hours; the life of LT95 of the device added the RCLEL layer is increased by 2.15 times, which can increasingly prove that adding the RCLEL layer is conducive to enhancing the life of OLED devices.

The invention discloses an OLED device, by configuring a RCLEL layer between the electron transport layer and the light emitting layer, and/or the light emitting layer and the hole transport layer, and/or the hole injection layer and the hole transport layer, the RCLEL layer restricts the accumulation of charges in the interface of the electron transport layer and the light emitting layer and the interface of the hole transport layer and the light emitting layer, and prevents the accumulated charges forming non-light-emitting center, reduces the decline of the device, thereby increasing the life of the device; and the RCLEL layer also prevents the diffused ions and impurities entering the light emitting layer, thereby reducing the luminescent quenching caused by the diffused ions and impurities; the material of the RCLEL layer has reversible electrochemical redox properties, so as to slow down the metamorphism of the material in the transmission process of electrons and holes and slow down the decline of the device and improve the life of the device.

The foregoing is only the preferred embodiments of the invention, not thus limiting embodiments and scope of the invention, those skilled in the art should be able to realize that the schemes obtained from the content of specification and figures of the invention are within the scope of the invention.

What is claimed is:

1. An OLED device, comprising an electron transport layer, a light emitting layer, a hole transport layer and a hole injection layer, stacked successively;
wherein a RCLEL layer (Restricted Charge Accumulation Induced Lifetime Enhancement Layer) is disposed between the electron transport layer and the hole injection layer to balance carrier mobility in interfaces of layers, and prevent an accumulation of charge at the film interface.

2. The OLED device according to claim 1, further comprising a first RCLEL layer disposed between the electron transport layer and the light emitting layer

3. The OLED device according to claim 2, further comprising a second RCLEL layer disposed between the light emitting layer and the hole transport layer.

4. The OLED device according to claim 2, wherein electron mobility of the first RCLEL layer is greater than electron mobility of the electron transport layer, so as to prevent an accumulation of charges at a contact interface of the light emitting layer and the electron transport layer.

5. The OLED device according to claim 2, wherein hole mobility of the second RCLEL layer is greater than hole mobility of the hole transport layer to prevent an accumulation of charges at the contact interface of the light emitting layer and the hole transport layer.

6. The OLED device according to claim 2, wherein materials of the first RCLEL layer, the second RCLEL layer and the RCLEL layer have reversible electrochemical redox properties.

7. The OLED device according to claim 6, wherein the materials of the first RCLEL layer, the second RCLEL layer and the RCLEL layer are different.

8. The OLED device according to claim 2, wherein thicknesses of the first RCLEL layer, the second RCLEL layer and the RCLEL layer are 5-500 Angstroms.

9. The OLED device according to claim 2, wherein triplet state energy levels of the first RCLEL layer and the second RCLEL layer are both higher than triplet state energy level of the light emitting layer.

10. The OLED device according to claim 7, wherein the material of the first RCLEL layer is an electron transport material or a hole blocking material, the material of the second RCLEL layer is a hole transport material or an electron blocking material, and the material of the RCLEL layer is a hole injection material or a hole transport material.

11. The OLED device according to claim 1, further comprising: a substrate, an anode, a buffer layer and a cathode on the electron transport layer, stacked successively under the hole injection layer.

12. The OLED device according to claim 1, wherein materials of the RCLEL layer and the electron transport layer are the same.
